(19) United States
(12) Patent Application Publication
(10) Pub. No.: US 2014/0345686 A1
(43) Pub. Date: Nov. 27, 2014

(54) HIGH-THROUGHPUT CONTINUOUS GAS-PHASE SYNTHESIS OF NANOWIRES WITH TUNABLE PROPERTIES

(71) Applicant: QUNANO AB, Lund (SE)

(72) Inventors: Magnus Heurlin, Furulund (SE); Martin H. Magnusson, Malmo (SE); Knut Deppert, Lund (SE); Lars Samuelson, Malmo (SE)

(21) Appl. No.: 14/375,982

(22) PCT Filed: Feb. 1, 2013
(86) PCT No.: PCT/IB2013/000626

§ 371 Date: Jul. 31, 2014

Related U.S. Application Data
(60) Provisional application No. 61/594,402, filed on Feb. 3, 2012.

(51) Int. Cl. H01L 29/04; H01L 29/20; C30B 29/40; H01L 31/0352; C30B 25/00; H01L 29/06; H01L 31/0304

(52) U.S. Cl. CPC H01L 29/045; H01L 29/0673; H01L 29/20; H01L 31/0304; H01L 31/035236; C30B 25/00; C30B 29/40
USPC 136/256; 257/627; 117/87

(57) ABSTRACT

A method for forming wires, including providing catalytic seed particles suspended in a gas, providing gaseous precursors that comprise constituents of the wires to be formed and growing the wires from the catalytic seed particles. The wires may be grown in a temperature range between 425 and 525 C and may have a pure zincblende structure. The wires may be III-V semiconductor nanowires having a Group V terminated surface and a <111>B crystal growth direction.

### FIELD

The present invention is directed to the synthesis of nanowires, specifically to gas phase synthesis of nanowires.

### BACKGROUND

Semiconductor nanowires are key building blocks for the next generation light-emitting diodes¹, solar cells² and batteries³. To fabricate functional nanowire-based devices on an industrial scale requires an efficient methodology that enables the mass-production of nanowires with perfect crystallinity, reproducible and controlled dimensions and material composition, as well as low cost. So far, there have been no reports of reliable methods that can satisfy all of these requirements.

### SUMMARY

An embodiment relates to a method for forming wires, including providing catalytic seed particles suspended in a gas, providing gaseous precursors that comprise constituents of the wires to be formed and growing the wires from the catalytic seed particles, for example in a temperature range between 425 and 525 C. The wires may have a pure zincblende structure.

Another embodiment relates to a method for forming III-V semiconductor nanowires including providing catalytic seed particles suspended in a gas, providing gaseous precursors that comprise constituents of the nanowires to be formed and growing the wires from the catalytic seed particles using the gaseous precursors while the catalytic seed particles are suspended in the gas, wherein the III-V semiconductor nanowires have a Group V terminated surface and a <111>B crystal growth direction.

### BRIEF DESCRIPTION OF THE DRAWINGS

FIG. 1 is a schematic illustration of a device and method of Aerotaxy™ growth of nanowires according to an embodiment.

FIGS. 2a-2d are scanning electron microscope images of GaAs nanowires grown by Aerotaxy™ under different growth conditions; nanowires grown with 2a) 35, 2b) 50, 2c) 70 and 2d) 120 nm diameter Au agglomerates.

FIGS. 2e-2h are scanning electron microscope images of GaAs nanowires grown by Aerotaxy™ under different growth conditions; nanowires grown with furnace temperatures of 2e) 450, 2f) 500, 2g) 550 and 2h) 600° C., using 50 nm Au agglomerates and a growth time of 1 s.

FIG. 2i is a graph illustrating the temperature dependence of the nanowire length. The error bars indicate the standard deviation of the measured nanowire length.

FIGS. 2j-2k are scanning electron microscope images of GaAs nanowires grown with reactor tube diameters of 2j) 18 and 2k) 32 mm, resulting in growth times of approximately 0.3 and 1 s.

FIGS. 3a-3d are transmission electron microscope images of nanowires grown at temperatures of 3a) 450, 3b) 500, 3c) 550 and 3d) 600° C. The nanowires were grown with a 50 nm Au agglomerate and a growth time of 1 s.

FIG. 4 is a photoluminescence spectra of eight small nanowire ensembles at 4 K on nanowires grown from 50 nm Au agglomerates at a growth temperature of 625° C., and a growth time of approximately 0.3 s. The average peak energy and FWHM are 1.513 eV and 23 meV respectively.

FIG. 5 is a ball and stick model illustrating a zincblende crystal structure.

FIG. 6 is an Arrhenius plot of nanowire growth rate. An activation energy of 97 kJ/mol can be extracted in the temperature range 450 to 550° C. indicated by the dashed line. The error bars indicate the standard deviation of the measured growth rate.

FIG. 7 is a scanning electron microscope (SEM) image of as deposited nanowires.

FIGS. 8(a)-8(d) are a transmission electron microscope (TEM) images of nanowires of FIG. 3; nanowires grown at (a) 450, (b) 500, (c) 550 and (d) 600° C. The viewing direction is <110>.

FIG. 9(a) is a TEM image of a nanowire used for growth direction determination by Convergent-Beam Electron Diffraction (CBED). Fig. (b) is a selected area diffraction pattern from the same nanowire with the two rows of reflections used for CBED indicated. Fig. (c) is a detail of the CBED pattern for the G=000, 002 and 004 reflections showing constructive interference in the 002 disc. Fig. (d) is the corresponding CBED pattern for −G, which shows destructive interference.

FIG. 10 is a TEM image, recorded in a <110> viewing direction, of a nanowire from the same growth run as those used for the photoluminescence measurements in FIG. 4.

FIG. 11 is a SEM image showing as-deposited nanowires on a Si substrate. Some nanowires show alignment with the electric field lines which are perpendicular to the substrate.

### DETAILED DESCRIPTION

Embodiments of the invention show how Aerotaxy™, an aerosol-based growth method⁴ (as described in PCT Published Application WO 11/142,717 (the '717 publication), assigned to Qunano AB and hereby incorporated by reference in its entirety), can be used to continuously grow nanowires with nanoscale-controlled dimensions, high degree of crystallinity and at a remarkable growth rate. In the Aerotaxy™ approach, catalytic size-selected aerosol particles, such as Au, induce nucleation and growth of nanowires (e.g. GaAs nanowires) with a growth rate greater than 0.1 μm/s, such as 0.5-1 μm/s, which is 20-1000 times faster than previously reported for traditional substrate-based III-V nanowire-growth⁵⁻⁷. In the Aerotaxy™ method, the nanowires are not growth rooted to a substrate. That is, in contrast to conventional methods which require growth from a single crystal substrate, the nanowires in the Aerotaxy™ method grown in a gas/aerosol phase without a substrate. The method enables sensitive and reproducible control of the nanowire dimensions and shape, and thus controlled optical and electronic properties, by varying growth temperature, time, and Au particle size. Photoluminescence measurements reveal that even as-grown nanowires have good optical properties and excellent spectral uniformity. Detailed transmission electron microscopy investigations show that the Aerotaxy™-grown nanowires form along the <111>B crystallographic direction, which is also the preferred growth direction for III-V nanowires seeded by Au particles on a single-crystal substrate. In an embodiment, at least 99% of the nanowires have a Group V terminated surface and a <111>B crystal growth direction. The continuous and potentially high-throughput method can be expected to significantly reduce the cost of producing high quality nanowires and may enable the low cost realization of nanowire-based devices on an industrial scale.

Nanowires are nanoscale structures that have a diameter or width less than 1 micron, such as 2-500 nm, including 10-200 nm, for example 25-100 nm or 100-200 nm, such as 150-180 nm (e.g., for longitudinal nanowire solar cells). The length, however, may be much greater than 1 micron.

Semiconductor nanowires are typically grown by a bottom up approach where metal particles positioned on top of a single-crystalline substrate enhance growth in one dimension (1-D) forming high aspect ratio nanostructures.⁸ The nanowire growth mechanism allows sensitive control of the nanowire dimensions, crystal structure and material composition, for example doping⁹ or heterostructure design¹⁰, if the growth method used is flexible enough to accommodate a wide set of growth parameters. Common methods for producing these structures include metal organic vapour phase epitaxy (MOVPE), molecular beam epitaxy, and chemical beam epitaxy. However, these methods are slow compared to other methods, as well as costly because of the need for expensive single-crystal substrates. Alternative approaches based on, for example, solution^{11,12} and gas phase¹³ growth, while potentially cheaper, are typically associated with restrictions or only allow poor control of basic nanowire properties such as crystallinity, diameter, length and shape. An Aerotaxy™-based growth method can overcome all of these issues when growing nanowires. The principle of Aerotaxy™, is based on the formation and manipulation of nanoparticles and nanowires in a continuous stream of gas. Aerotaxy™ eliminates the need for single-crystal substrates to induce nucleation and circumvents the limitations of batch-wise growth by providing a continuous process. Comparing the growth equipment with a 2-inch MOVPE reactor, where Au particles are deposited on a wafer at a density of 1 μm⁻², it is possible to increase the nanowire production rate by 50 times using the current Aerotaxy™ system (discussed in more detail below). For example, 100,000 or more nanowires (e.g. more than 500,000, such as more than 1 million nanowires) can be made in a single Aerotaxy™ reactor. For example, for a continuous Aerotaxy™ process, the number of nanowires inside the growth zone of a lab scale reactor at any given time is around 5 million (6×10⁵ nanowires per cm³, 8 cm³/s flow rate and 1 s residence time). Larger numbers may be produced in larger reactors and higher flow rates.

Because the high cost of single-crystal semiconductor devices has so far been a limiting factor in large-scale implementations of for example energy-relevant semiconductor applications, the Aerotaxy™-based nanowire-growth method described herein could provide a scalable methodology for fabricating large area nanowire-based devices.

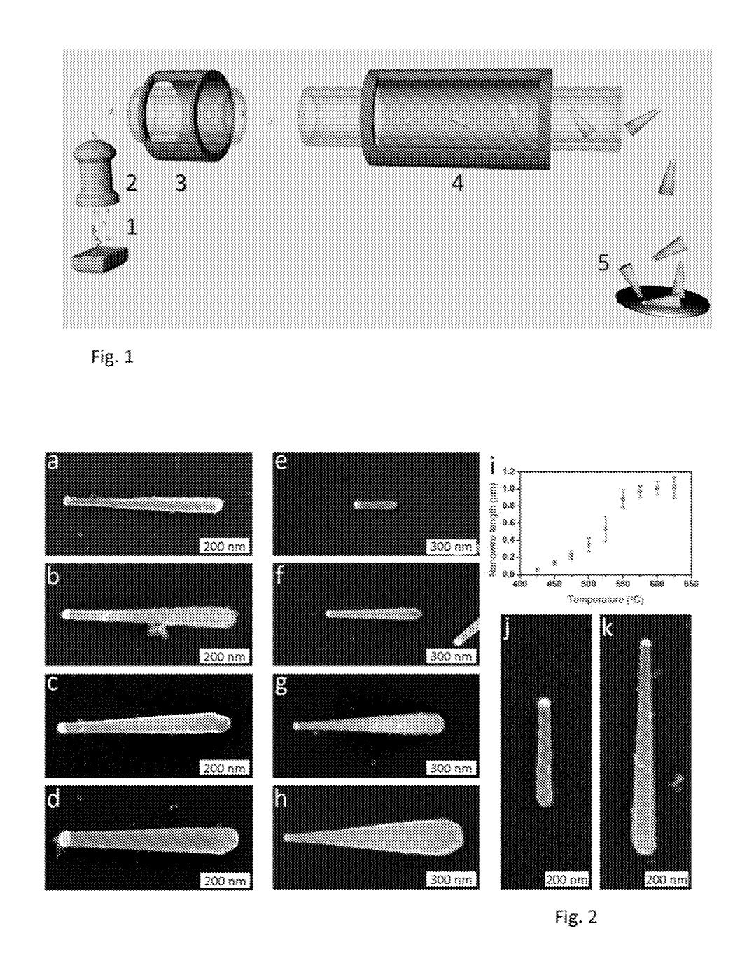

FIG. 1 illustrates an embodiment of a system and method for Aerotaxy™-growth of nanowires. In step 1 an aerosol of agglomerates of gold is formed. In step 2, the gold agglomerates are sorted according to size using a DMA. In step 3, the gold agglomerates are compacted into spherical particles. In step 4, the nanowires are grown. In step 5, the nanowires are collected for further processing (e.g., to be deposited on a substrate).

Au nanoparticles may be used to catalyze 1-D growth of GaAs nanowires all occurring in the aerosol phase (FIG. 1). However, other catalyst particles and other nanowire materials may also be used, e.g. Ni particles and semiconductor nanowires (such as Si, Ge, other III-V or II-VI, such as GaAs, GaP, GaN, GaSb, AlP, AlAs, AlN, AlSb, InP, InAs, InSb or ternary or quaternary combinations thereof), metal nanowires or insulating nanowires (e.g. SiO₂, Al₂O₃, etc.). The nanoparticles are size-selected with a high degree of control¹⁴ to allow sensitive tuning of the nanowire lateral dimension, and thereby material properties such as quantum confinement and electron scattering, which enables tailoring of the optical¹⁵ and electrical¹⁶ properties of the nanowires. The particle size selection is achieved by generating and size-selecting Au aerosol particles in a setup which consists of an evaporation-condensation step for the formation of Au agglomerates 1, a particle charger 2, a differential mobility analyser (DMA) for the size selection of agglomerates, and a sintering furnace 3 for particle compaction.¹⁷ A similar method has previously been successfully used to provide seed particles for gas phase growth of a related class of 1-D materials, carbon nanotubes, where it was possible to control and tune the diameter.¹⁸

To initiate the reaction forming the nanowires, the size-selected Au particles are mixed with reactants (precursors) carrying the constituents of the nanowire material, and exposed to an elevated temperature during a well-controlled growth time—in a heated tube furnace 4. In an embodiment, trimethylgallium (TMGa) and arsine (AsH₃) were used. These materials are commonly used for the growth of thin-film GaAs crystals and nanowires with MOVPE. According to current understanding of nanowire growth, an alloyed nanoparticle of Au—Ga should form and new atomic planes subsequently nucleate at the crystal-nanoparticle-vapour triple phase boundary¹⁹ during the time spent at the elevated temperature in the tube furnace. In an embodiment, the crystal-nanoparticle interface is not present at the start of the process but is generated on the nanoparticle surface through the formation of a GaAs crystallite from which the nanowire growth can propagate. The nanowires preferentially form under relatively low V/III ratios compared to Au particle nucleated nanowires grown with the same precursors using MOVPE. Since there is no substrate that can provide Ga to supersaturate the Au particle, this must instead be provided directly from the gas phase. A high V/III ratio would decrease this supersaturation inhibiting nanowire nucleation and instead favour GaAs particle formation. After the nanowires have formed they are transported, still in the aerosol phase, to a deposition chamber 5 where they are deposited on a surface of choice and may be assisted by an electric field, (e.g. whereby an electric polarization in the nanowires makes them align along the electrical field, as described in PCT Published Application WO 11/078,780 published on Jun. 30, 2011 and its U.S. national stage application Ser. No. 13/518,259, both of which are incorporated herein by reference in their entirety).

FIG. 2 illustrates scanning electron microscope images of GaAs nanowires grown by Aerotaxy™ under different growth conditions. FIGS. 2a-2d illustrate nanowires grown with 35, 50, 70 and 120 nm diameter Au agglomerates, respectively, at a furnace temperature of 525° C. After particle compaction and nanowire growth this results in average nanowire top diameters of 30, 41, 51 and 66 nm. FIGS. 2e-2h illustrate nanowires grown at furnace temperatures of 450, 500, 550 and 600° C., respectively, using 50 nm Au agglomerates and a growth time of 1 s. FIG. 2i is a graph illustrating the temperature dependence of the nanowire length. The error bars indicate the standard deviation of the measured nanowire length. FIGS. 2j-2k illustrate nanowires grown with reactor tube diameters of 18 and 32 mm, respectively, resulting in growth times of approximately 0.3 and 1 s. In each series of images, all other growth parameters except the one varied were kept constant.

Thus, the nanowire diameter, length and shape can be controlled by changing the Au particle size (FIGS. 2 a-d), the growth temperature (FIGS. 2 e-h) and/or the growth time (FIGS. 2 j-k), respectively. Controlling these parameters results in nanowires with reproducible properties which is preferable in large-scale semiconductor applications where millions of nanowires need to be incorporated in parallel to build up a functional device. The growth time is controlled by the gas velocity through the reactor tube (for a given furnace length) and can be varied by, for example, changing the reactor tube diameter. The Au particle size is determined by the DMA and Au particles may have diameters ranging from 5 to 80 nm. The effect of temperature is more complex than a change in particle size or growth time since it affects both the length (FIG. 2i) and shape of the nanowire. This is due to an increase in the reaction rate at higher temperatures, at both the Au particle-nanowire interface and on the side facets of the nanowire, phenomena that are well-known from conventional nanowire growth. The increased reaction rate at higher temperatures also leads to parasitic reactions between TMGa and AsH₃ in the gas phase which can form small GaAs particles, evident in FIG. 2g.

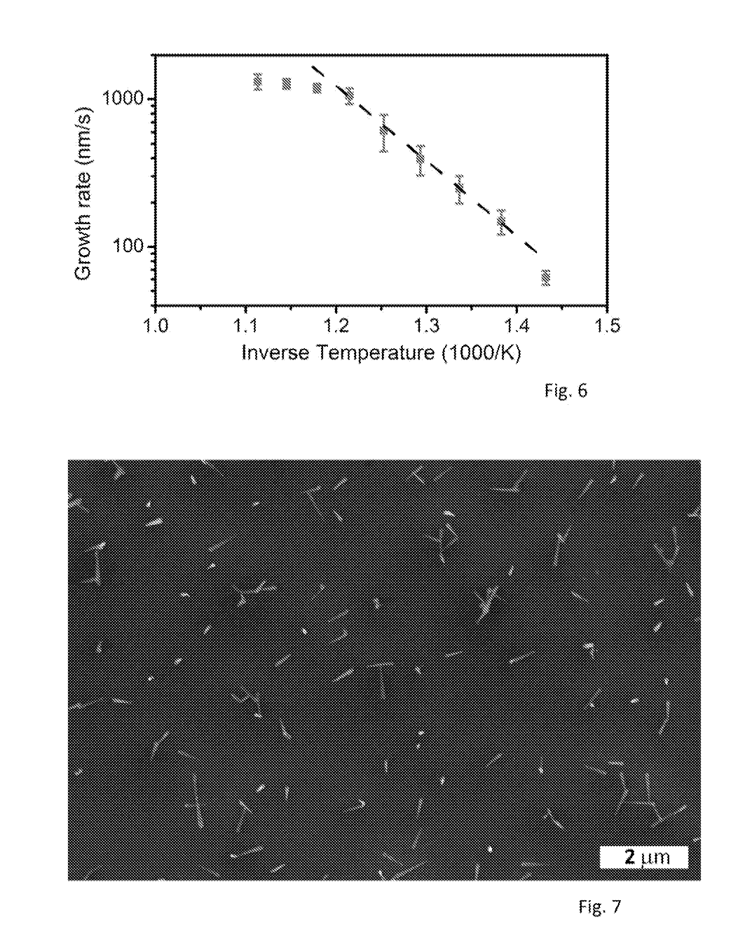

Investigations of the growth rate show that the axial growth rate, which can exceed 1 μm/s, has an Arrhenius dependence between 450 and 550° C. (FIG. 6). From this, an activation energy of 97 kJ/mol for the axial growth can be determined. This value is within the range of previous reports on the activation energy of substrate-nucleated GaAs nanowires (67-102 kJ/mol^{20,21}). The rate-limiting step for Aerotaxy™-grown nanowires may not differ in any significant way. However, an apparent difference is the absence of a reduced growth rate at higher temperatures for Aerotaxy™-grown nanowires. When nanowires are seeded on a native single-crystalline substrate, growth on the substrate surface becomes more dominant at higher temperatures, reducing the nanowire growth rate. The absence of a substrate in Aerotaxy™ eliminates this effect, enabling a high growth rate to be maintained over a broader temperature interval.

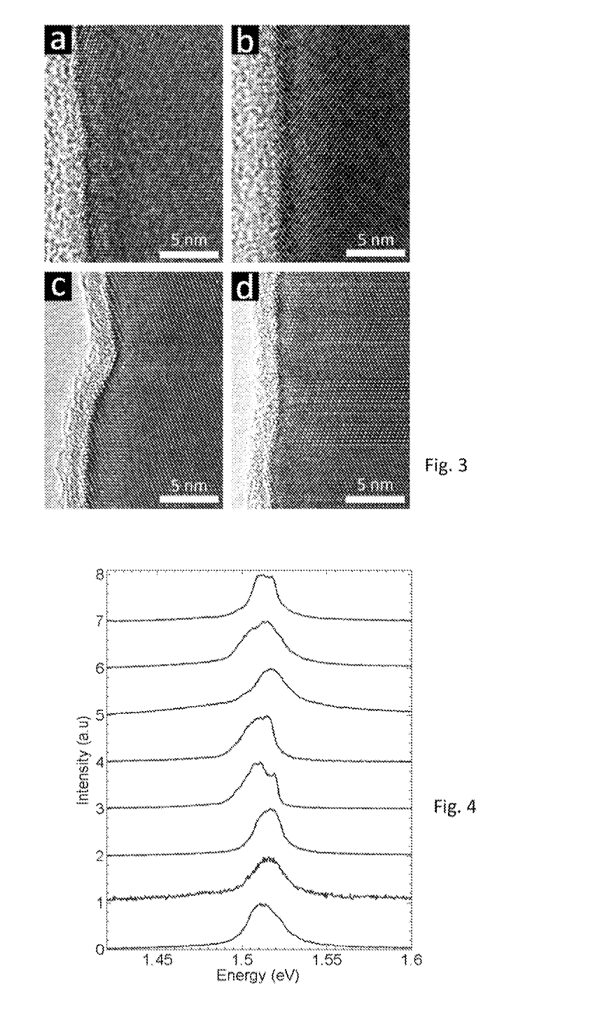

FIGS. 3a-3d illustrate the temperature dependence of the nanowire crystal structure. The figures show TEM images of nanowires grown at temperatures of 3a) 450, 3b) 500, 3c) 550 and 3d) 600° C. The nanowires were grown with 50 nm Au agglomerates and a growth time of 1 s. The viewing direction is <110>.

In addition to affecting the growth rate, the growth temperature also affects the crystal structure of the nanowires (FIG. 3 a-d). III-V nanowires commonly exhibit a polytypic crystal structure where the cubic zinc-blende and hexagonal wurtzite phases are intermixed²². Between 425 (the lowest temperature exhibiting nanowire growth) and 525° C. the nanowires exhibit a pure zinc-blende crystal structure (illustrated in FIG. 5), where polytypism-related modulations in the potential landscape for an electron travelling in the axial direction of a nanowire are avoided (FIGS. 3a,b). However, this is not a large problem for certain device applications, such as solar cells, and the zinc blende structure is not a necessary feature of the present invention. As illustrated in FIG. 5, the zinc-blende structure includes two different atoms in which the two atom types form two interpenetrating face-centered cubic lattices. The zincblende structure has tetrahedral coordination. That is, each atom's nearest neighbors consist of four atoms of the other type, positioned like the four vertices of a regular tetrahedron. The arrangement of atoms in the zincblende structure is the same as diamond cubic structure, but with alternating types of atoms at the different lattice sites.

At higher growth temperatures, intermixing of the crystal phases is observed with the formation of twin planes and small wurtzite inclusions in the zinc-blende dominated nanowires (FIGS. 3c, d). The relatively large temperature interval in which single crystal phase nanowires can be grown using the Aerotaxy™ technique further demonstrates the applicability of this technique and its ability to control nanowire properties.

The nanowire crystal-growth direction was determined to be <111> in more than 99% of the investigated nanowires, using high-resolution transmission electron microscopy (TEM) images. Ten nanowires were further investigated using convergent beam electron diffraction (CBED) in order to differentiate the two types of <111> growth directions, which can have either a group III- or a group V-terminated surface on the corresponding {111} planes. In all cases the growth was found to have occurred in the group V-terminated <111>B direction (FIG. 9), as is most commonly reported for substrate grown III-V nanowires. This shows that the growth direction and polarity of nanowires remain the same as when using a substrate during growth, indicating that this fundamental property is dictated at the seed particle/nanowire interface and not by the substrate.

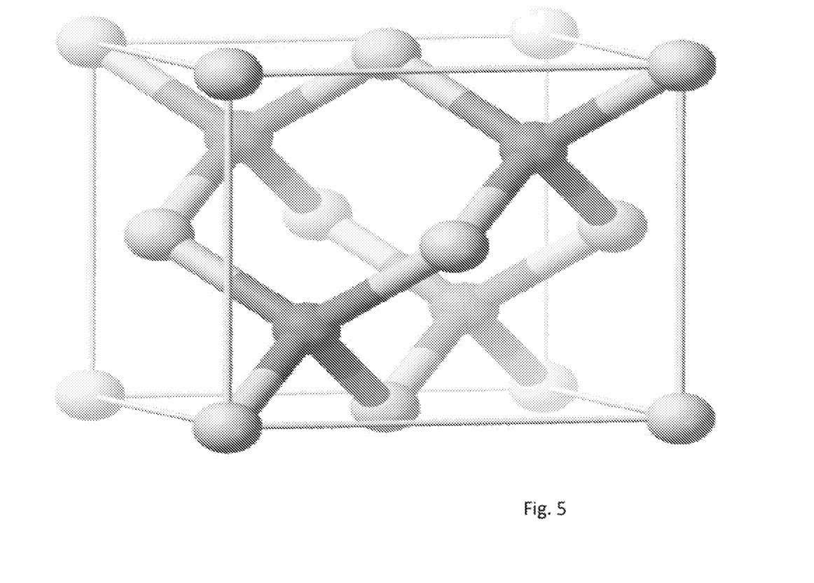

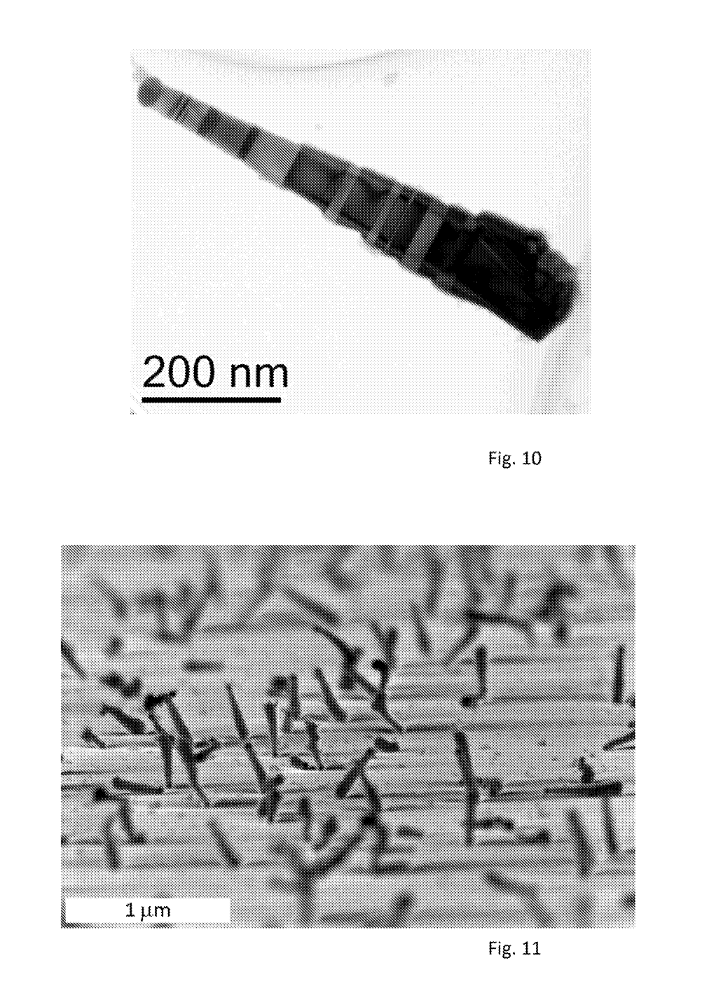

Photoluminescence measurements reveal spectra of excellent uniformity (FIG. 4) despite the fact that no surface treatment or high bandgap passivation was used to reduce surface recombination, indicating that as-grown nanowires have good optical properties. A peak maximum can be observed at 1.514 eV which falls in the known range for bound and free excitons in bulk GaAs (1.513-1.516 eV²³), and corresponds well with previous reports of MOVPE-grown nanowires²⁴. The average peak full-width-half-maximum (FWHM) of eight measured spectra is 23 meV. The measurements were performed on nanowires grown using an Au agglomerate size of 50 nm, growth temperature of 625° C., and growth time of 0.3 s. Nanowires grown during this shorter time typically show a lower density of stacking faults (e.g. a defect that alters the periodic sequence of stacking of the atomic layers, such as hexagonal ABAB to face centered cubic ABC) compared to nanowires grown during a longer time (˜1 s) at the same temperature. TEM of nanowires grown with the parameters stated above show a twinned zinc-blende crystal structure where the twin distance varies from a few nanometers up to 60 nm (FIG. 10). In view of this, the luminescence observed below the main peak can be attributed to type-II transitions at the twin plane boundaries²⁵. The photoluminescence results are better, in terms of homogeneity and FWHM, than previous reports of GaAs nanowires grown in a solution or gas phase where only very broad luminescence, if any, was observed^{26,27}. The reported data is better or comparable to that of GaAs nanowires grown on single crystalline Si²⁸. Increased control of nanowire polytypism at high nanowire growth temperatures and the addition of a surface passivating shell could improve the optical characteristics in order to reach state of the art GaAs nanowires grown on a native substrate which can exhibit FWHM as narrow as 3 meV²⁴.

Aerotaxy™-based growth method may have a significant impact on how the field of nanoscale devices, primarily those based on nanowires, will develop in the future. The method is general and is applicable to other common precursor materials and seed nanoparticle formation techniques. For large-area applications the throughput, i.e., the number of nanowires produced per unit time may be of high importance. Production rates that exceed those available for substrate nucleated nanowires have been demonstrated. Because the system illustrated in FIG. 1 is currently limited by the number of seed particles that can be produced, an increase in particle production will result in a similar increase in nanowire production and thus a reduction in cost for nanowire fabrication. Increasing particle production is possible by, e.g., adding additional high-temperature furnaces for agglomerate formation or by implementing different nanoparticle generation processes with higher throughput, e.g., spark or arc discharge.

Doping of the nanowires and, in particular, the formation of pn-junctions or p-i-n junctions during Aerotaxy™ is also desirable. Results from secondary ion mass spectroscopy measurements on single-segment nanowires show that Zn is incorporated during growth in the presence of the precursor DEZn. A pn-junction containing segments with different dopants and doping concentrations may be formed by providing sequential growth furnaces where different precursors are introduced in each furnace or by inserting gases in different places in the same furnace. In an embodiment, the doping profile may be non-uniform if the dopant precursor is depleted during growth. This may affect the contact formation. The system may be optimized by optimizing the process design along with chemical and kinetic modeling.

Another consideration for some device and system applications is the ability to align the non-substrate-bound nanowires. This can be done by, e.g., electric fields, which has been previously demonstrated to result in nanowire alignment with remarkably high yields²⁹. The use of charged aerosol particles also opens up the possibility of deposition and simultaneous alignment (FIG. 11) of nanowires directly from the gas phase. To control the vertical orientation of the p- and n-segments in the alignment process of nanowires containing pn-junctions, which is important for solar cell and to some extent LED applications, the built-in potential of the pn-junction can be exploited, where each nanowire would form small dipoles under illumination, for example, as described in U.S. patent application Ser. No. 13/518,259 which is a U.S. national stage of PCT published application WO 2011/078780 filed on Dec. 22, 2010, published on June 30, both of which are incorporated herein by reference in their entirety.

As an alternative to the above methods, the Aerotaxy™-produced nanowires can also be harvested directly from the gas phase into a liquid using various scrubber techniques. The nanowire solution can thereafter be stored and used in further processing steps where the nanowires can be deposited using for example fluidic alignment³⁰, which might be ideal for thermoelectric applications^{31,32}.

However, many applications, such as, Li-ion batteries do not require nanowire alignment. Li-ion batteries with Si nanowires as the anode material have received significant attention over the past few years because Si has the highest known theoretical charge potential and in nanowire form a reduction in performance deterioration resulting from charge cycling has been observed³. With further developments in the areas of growth and device processing Aerotaxy™ could thus provide a scalable production of perfect semiconductor nanowire device structures for diverse applications such as large-area solar cells, solid state lighting and Li-ion batteries.

FIG. 4 shows photoluminescence spectra of eight small nanowire ensembles at 4 K on nanowires grown from 50 nm Au agglomerates at a growth temperature of 625° C., and a growth time of approximately 0.3 s. No surface treatment or high bandgap passivation was used to reduce surface recombination. The photoluminescence measurements reveal spectra of excellent uniformity despite the lack of surface treatment or high bandgap passivation, indicating that as-grown wires have good optical properties.

Specifically, Au agglomerates are formed by an evaporation-condensation process in a high temperature furnace working between 1750-1850° C. Size selection of the Au agglomerates is performed using a differential mobility analyser (DMA) with a sheath flow of 10 l/min and a varied voltage determining the Au agglomerate size. For the agglomerates to be size selected, they are provided a single electron charge quantum supplied by a ⁶³Ni β-radiation-charger positioned before the DMA. After size selection, the agglomerates are compacted into spherical particles using a sinter furnace working at 450° C. The Au particles are mixed with the precursor gases AsH₃ and TMGa; the AsH₃ being supplied from a gas bottle through a mass-flow controller (MFC). The TMGa was supplied from a standard temperature- and pressure-controlled metal-organic bubbler with H₂ carrier gas supplied through a second MFC. The AsH₃ molar fraction was 3*10⁻⁶ with a total gas flow of 1.68 l/min and the V/III ratio was 0.9 in all experiments. The main carrier gas was N₂. The mixture of Au particles and gas was passed through a reaction furnace consisting of a sintered Al₂O₃ reactor tube surrounded by a resistive heater. The reactor tube was exchangeable and two tubes with different inner diameters (18 and 32 mm) were used in the experiments. After the reaction furnace the nanowires can either be passed to an electrometer measuring the amount of charge in the aerosol or to a deposition chamber where the nanoparticles/nanowires can be deposited by assistance of an electric field. The electric field strength in the deposition chamber was 10⁵ V/m. During the experiments a Si substrate was used to collect the nanowires.

Characterization. The samples were investigated with a scanning electron microscope, operated at 10 kV, and selected samples were singled out for further analysis to determine atomic structure and optical properties. The crystal structure was investigated using a JEOL 3000F TEM (300 kV) with a point resolution of 1.7 Å. The crystal polarity was determined using CBED by observing the asymmetrical contrast in the ±002 discs, which arises from dynamical diffraction when odd-indexed, high-order reflections are excited simultaneously³³.

The CBED measurements were made by tilting approximately 7° in the (002) plane until the Bragg condition was fulfilled for either the 002 or the 00-2 and two weak, odd-indexed reflections (-1-1-11 and -1-1 9 in the case of 00-2). After setting the convergence angle to approximately 3.7 mrad a bright interference pattern was seen in the centre of the 00-2 disc (dark in the 002 disc). This difference allowed the diffraction pattern to be indexed unambiguously³³. A comparison with GaAs nanowires grown by MOVPE on <111>B substrates was used to resolve the 180° ambiguity due to possible image inversions.

Optical properties were investigated using a micro-photoluminescence setup at 4 K with a spectral resolution of 1.3 meV. The 532 nm line from a frequency-doubled Nd-YAG laser was used as the excitation source, with an intensity of approximately 10 W/cm². To measure on single nanowires and small nanowire ensembles, some nanowires were transferred to an Au-coated Si substrate.

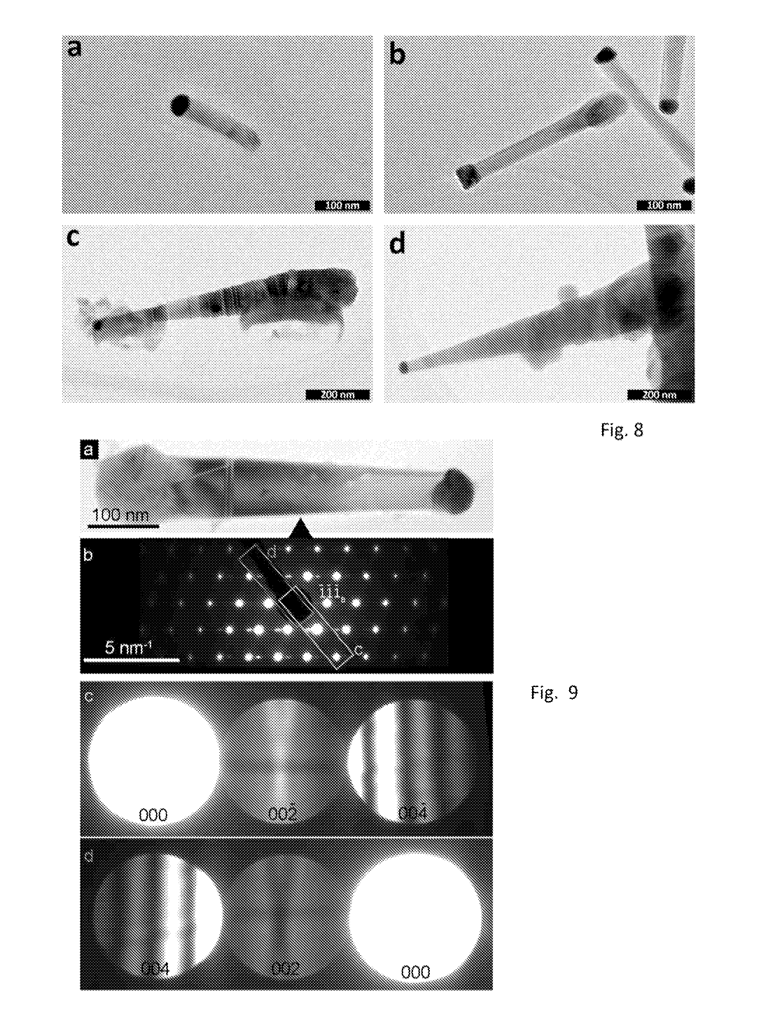

A comparison between MOVPE and Aerotaxy™ is presented in terms of nanowire production rate. FIG. 6 presents the Arrhenius plot to accompany FIG. 2i above. FIG. 7 presents an overview SEM image of as-deposited nanowires displaying their uniformity. FIG. 8 shows TEM images to accompany FIG. 3a-d above. FIG. 9, discussed in more detail below, explains the CBED measurement made to identify the polarity of the nanowire growth direction. In FIG. 10, a TEM image of a typical nanowire from the growth run in which the PL (FIG. 4) was performed is shown. FIG. 11 shows a side view of as-deposited nanowires showing alignment of some nanowires with the E-field used to deposit the nanowires.

In the Aerotaxy™ system illustrated in FIG. 1, nanowire production is limited by the amount of Au particles supplied. In an embodiment, 1.7*10⁹ Au particles are supplied per minute, which equates to 1.0*10¹¹ nanowires per hour.

MOVPE is limited by the size of the substrate which can be inserted into the reactor and the time each growth run takes including heating up, cooling down as well as loading/unloading. A typical research tool (that can be compared to our Aerotaxy™ system) can handle one 2 inch wafer. A run in which 1 μm nanowires are produced typically takes 1 hour including loading/unloading. If Au particles are deposited on the wafer at a density of 1 μm⁻², it would be possible to produce 2.0*10⁹ nanowires per hour or 50 times fewer than the Aerotaxy™ process.

Improvements can be made to both processes in order to optimize and increase the number of nanowires formed. For the Aerotaxy™ process the number of Au particles produced per unit time may be increased. This can, for example, be accomplished by connecting several Au particle producing furnaces in parallel. Increasing the number of nanowires using MOVPE would require either a larger growth reactor, which can handle larger/more substrates, or a higher density of Au particles. However, using a higher density would require some form of advanced lithography if a mono-disperse Au size distribution is to be maintained.

The nanowire length in FIG. 2i and FIG. 6 was measured by TEM in order to avoid measuring on nanowires standing at an inclined angle on the deposition substrate. The number of nanowires measured in each measurement point is outlined in Table 1 below.

TABLE 1
Number of nanowires measured in each measurement point in FIGS. 2i and 6.

| Temperature (° C.) | Number of nanowires measured |
|---|---|
| 425 | 6 |
| 450 | 8 |
| 475 | 4 |
| 500 | 8 |
| 525 | 4 |
| 550 | 10 |
| 575 | 8 |
| 600 | 10 |
| 625 | 6 |

FIG. 6 is an Arrhenius plot of the nanowire growth rate. An activation energy of 97 kJ/mol can be extracted in the temperature range 450 to 550° C. as indicated by the dashed line. The error bars indicate the standard deviation of the measured growth rate.

FIG. 7 is a SEM image of as deposited nanowires. Both nanowires that are standing and lying on the substrate are visible complicating nanowire length comparisons. Nanowires were grown using 35 nm Au agglomerates at a furnace temperature of 525° C.

FIGS. 8(a)-8(d) are TEM images of nanowires also illustrated in FIG. 3. The nanowires were grown at 450, 500, 550 and 600° C., respectively. The viewing direction is <110>.

FIG. 9 illustrates the procedure for differentiating the 111 and -1-1-1 reflections in the diffraction pattern using CBED. The method relies on setting up a 3-beam condition where one of the 002 reflections and the odd indexed 1,1,11 and 1,1,9 type reflections (not shown in FIG. 9) are excited simultaneously. There is a phase difference between the electrons scattered directly into the 002 disc and the electrons dynamically scattered via the odd-indexed reflections, which depend on which of the two 002 discs that is involved. This results in constructive interference for the As-terminated directions (in GaAs), allowing the diffraction pattern to be indexed unambiguously. The same method had been used previously on a GaAs nanowire sample with a known growth direction in order to determine the rotation caused by the projector lenses between imaging and diffraction mode. A total of 10 nanowires, grown at a temperature of 525° C. and an Au agglomerate size of 120 nm, were analyzed using this method.

FIG. 9(a) is a TEM image of one of the ten nanowires used for growth direction determination by CBED. FIG. 9(b) is a selected area diffraction pattern from the same nanowire with the two rows of reflections used for CBED indicated. FIG. 9(c) illustrates a detail of the CBED pattern for the G=000, 002 and 004 reflections showing constructive interference in the 002 disc. FIG. 9(d) illustrates the corresponding CBED pattern for −G, which shows destructive interference. This information allows the 111 type reflection in the growth direction (indicated in b) to be unambiguously identified as <111>B.

FIG. 10 is a TEM image, recorded in a <110> viewing direction, of a nanowire from the same growth run as those used for the PL measurements in FIG. 4. The crystal structure is zinc-blende, where the alternating bright and dark contrast originates different rotations of the crystal caused by twin planes at the boundaries.

FIG. 11 is a SEM image showing as-deposited nanowires on a Si substrate. Some nanowires show alignment with the electric field lines which are perpendicular to the substrate.

### REFERENCES, HEREBY INCORPORATED BY REFERENCE IN THEIR ENTIRETY

1 Qian, F., Grade\tilde{c}ak, S., Li, Y., Wen, C.-Y. & Lieber, C. M. Core/Multishell Nanowire Heterostructures as Multicolor, High-Efficiency Light-Emitting Diodes. Nano Letters 5, 2287-2291 (2005).
2 Borgström, M. T. et al. Nanowires With Promise for Photovoltaics. IEEE Journal of Selected Topics in Quantum Electronics 17, 1050-1061 (2011).
3 Chan, C. K. et al. High-performance lithium battery anodes using silicon nanowires. Nat Nano 3, 31-35 (2008).
4 Deppert, K. & Samuelson, L. Self-limiting transformation of monodisperse Ga droplets into GaAs nanocrystals. Applied Physics Letters 68, 1409-1411 (1996).
5 Joyce, H. J. et al. Unexpected Benefits of Rapid Growth Rate for III-V Nanowires. Nano Letters 9, 695-701 (2008).
6 Borgström, M. T., Immink, G., Ketelaars, B., Algra, R. & Bakkers, E. P. A. M. Synergetic nanowire growth. Nat Nano 2, 541-544 (2007).
7 Ramdani, M. R. et al. Fast Growth Synthesis of GaAs Nanowires with Exceptional Length. Nano Letters 10, 1836-1841 (2010).
8 Yazawa, M., Koguchi, M., Muto, A., Ozawa, M. & Hiruma, K. Effect of one monolayer of surface gold atoms on the epitaxial growth of InAs nanowhiskers. Applied Physics Letters 61, 2051-2053 (1992).
9 Haraguchi, K., Katsuyama, T. & Hiruma, K. Polarization dependence of light emitted from GaAs p-n junctions in quantum wire crystals. Journal of Applied Physics 75, 4220-4225 (1994).
10 Björk, M. T. et al. One-dimensional Steeplechase for Electrons Realized. Nano Letters 2, 87-89 (2002).
11 Holmes, J. D., Johnston, K. P., Doty, R. C. & Korgel, B. A. Control of Thickness and Orientation of Solution-Grown Silicon Nanowires. Science 287, 1471-1473 (2000).
12 Wang, F. et al. Solution-Liquid-Solid Growth of Semiconductor Nanowires. Inorganic Chemistry 45, 7511-7521 (2006).
13 Duan, X. & Lieber, C. M. General Synthesis of Compound Semiconductor Nanowires. Advanced Materials 12, 298-302 (2000).
14 Karlsson, L., Deppert, K. & Malm, J.-O, Size Determination of Au Aerosol Nanoparticles by Off-Line TEM/STEM Observations. Journal of Nanoparticle Research 8, 971-980 (2006).
15 Gudiksen, M. S., Wang, J. & Lieber, C. M. Size-Dependent Photoluminescence from Single Indium Phosphide Nanowires. The Journal of Physical Chemistry B 106, 4036-4039 (2002).
16 Ford, A. C. et al. Diameter-Dependent Electron Mobility of InAs Nanowires. Nano Letters 9, 360-365 (2008).
17 Magnusson, M. H., Deppert, K., Maim, J.-O., Bovin, J.-O. & Samuelson, L. Size-selected gold nanoparticles by aerosol technology. Nanostructured Materials 12, 45-48 (1999).
18 Kim, S. H. & Zachariah, M. R. Gas-phase growth of diameter-controlled carbon nanotubes. Materials Letters 61, 2079-2083, doi:10.1016/j.matlet.2006.08.031 (2007).
19 Wacaser, B. A. et al. Preferential Interface Nucleation: An Expansion of the VLS Growth Mechanism for Nanowires. Advanced Materials 21, 153-165 (2009).
20 Soci, C., Bao, X.-Y., Aplin, D. P. R. & Wang, D. A Systematic Study on the Growth of GaAs Nanowires by Metal-Organic Chemical Vapor Deposition. Nano Letters 8, 4275-4282 (2008).
21 Borgström, M., Deppert, K., Samuelson, L. & Seifert, W. Size- and shape-controlled GaAs nano-whiskers grown by MOVPE: a growth study. Journal of Crystal Growth 260, 18-22 (2004).
22 Caroff, P., Bolinsson, J. & Johansson, J. Crystal Phases in III-V Nanowires: From Random Toward Engineered Polytypism. IEEE Journal of Selected Topics in Quantum Electronics 17, 829-846 (2011).
23 Bogardus, E. H. & Bebb, H. B. Bound-Exciton, Free-Exciton, Band-Acceptor, Donor-Acceptor, and Auger Recombination in GaAs. Physical Review 176, 993-1002 (1968).
24 Morral, A. F. Gold-Free GaAs Nanowire Synthesis and Optical Properties. IEEE Journal of Selected Topics in Quantum Electronics 17, 819-828 (2011).
25 Heiss, M. et al. Direct correlation of crystal structure and optical properties in wurtzite/zinc-blende GaAs nanowire heterostructures. Physical Review B 83, 045303 (2011).
26 Dong, A., Yu, H., Wang, F. & Buhro, W. E. Colloidal GaAs Quantum Wires: Solution-Liquid-Solid Synthesis and Quantum-Confinement Studies. Journal of the American Chemical Society 130, 5954-5961 (2008).
27 Duan, X., Wang, J. & Lieber, C. M. Synthesis and optical properties of gallium arsenide nanowires. Applied Physics Letters 76, 1116-1118 (2000).
28 Moewe, M., Chuang, L. C., Crankshaw, S., Chase, C. & Chang-Hasnain, C. Atomically sharp catalyst-free wurtzite GaAs/AlGaAs nanoneedles grown on silicon. Applied Physics Letters 93, 023116-023113 (2008).
29 Freer, E. M., Grachev, O., Duan, X., Martin, S. & Stumbo, D. P. High-yield self-limiting single-nanowire assembly with dielectrophoresis. Nat Nano 5, 525-530 (2010).
30 Huang, Y., Duan, X., Wei, Q. & Lieber, C. M. Directed Assembly of One-Dimensional Nanostructures into Functional Networks. Science 291, 630-633 (2001).
31 Dresselhaus, M. S. et al. New Directions for Low-Dimensional Thermoelectric Materials. Advanced Materials 19, 1043-1053 (2007).
32 Boukai, A. I. et al. Silicon nanowires as efficient thermoelectric materials. Nature 451, 168-171 (2008).
33 Taftø, J. & Spence, J. C. H. A simple method for the determination of structure-factor phase relationships and crystal polarity using electron diffraction. Journal of Applied Crystallography 15, 60-64 (1982).

Although the foregoing refers to particular preferred embodiments, it will be understood that the invention is not so limited. It will occur to those of ordinary skill in the art that various modifications may be made to the disclosed embodiments and that such modifications are intended to be within the scope of the invention. All of the publications, patent applications and patents cited herein are incorporated herein by reference in their entirety.

What is claimed is:

1. A method for forming wires, comprising:
providing catalytic seed particles suspended in a gas;
providing gaseous precursors that comprise constituents of the wires to be formed; and
growing the wires from the catalytic seed particles,
characterized in at least one of growing the wires in a temperature range between 425 and 525 C, or the wires having a pure zincblende structure.

2. The method of claim 1, wherein the wires comprise one or more of Ga, Al or In and one or more of As, P, N or Sb.

3. The method of claim 1, wherein the wires comprise GaAs, GaP, GaN, GaSb, AlP, AlAs, AlN, AlSb, InP, InAs, InSb or ternary or quaternary combinations thereof.

4. The method of claim 1, wherein the wires are single crystal and have essentially no stacking faults.

5. The method of claim 1, wherein the wires grow at a rate greater than 0.1 microns/sec using the gaseous precursors while the catalytic seed particles are suspended in the gas.

6. The method of claim 5, wherein the growth rate comprises 0.5 to 1 microns/sec.

7. The method of claim 1, wherein the wires comprise semiconductor nanowires having a width or diameter less than 1 micron and the seed particles comprise metal nanoparticles.

8. The method of claim 1, wherein the wires comprise III-V semiconductor nanowires having a width or diameter of 2-500 nm, and the seed particles comprise metal nanoparticles provided in a form of an aerosol.

9. The method of claim 8, wherein the III-V semiconductor nanowires have a Group V terminated surface and a <111>B crystal growth direction.

10. The method of claim 8, wherein the metal nanoparticles comprise gold nanoparticles.

11. The method of claim 1, wherein the wires are grown in the temperature range between 425 and 525 C.

12. The method of claim 1, wherein the wires have the pure zincblende structure.

13. The method of claim 1, wherein the wires are grown in the temperature range between 425 and 525 C and the wires have the pure zincblende structure.

14. A method for forming III-V semiconductor nanowires, comprising:
providing catalytic seed particles suspended in a gas;
providing gaseous precursors that comprise constituents of the nanowires to be formed; and
growing the wires from the catalytic seed particles using the gaseous precursors while the catalytic seed particles are suspended in the gas, wherein the III-V semiconductor nanowires have a Group V terminated surface and a <111>B crystal growth direction.

15. The method of claim 14, wherein the nanowire growth rate comprises 0.5 to 1 microns/sec.

16. The method of claim 14, wherein the semiconductor nanowires have a width or diameter less than 1 micron and the seed particles comprise metal nanoparticles.

17. The method of claim 14, wherein the semiconductor nanowires have a width or diameter of 2-500 nm, and the seed particles comprise gold nanoparticles provided in a form of an aerosol.

18. The method of claim 14, wherein the nanowires comprise single crystal nanowires.

19. The method of claim 14, wherein the nanowires have a pure zincblende structure.

20. A plurality of III-V semiconductor nanowires, wherein at least 99% of the nanowires have a Group V terminated surface and a <111>B crystal growth direction.

21. The semiconductor nanowires of claim 20, wherein the nanowires are grown in a gas phase and are not growth rooted to a substrate.

22. The semiconductor nanowires of claim 20, wherein the plurality comprises at least 100,000 nanowires.

23. The semiconductor nanowires of claim 20, wherein the nanowires are located in a solar cell.
